(19) United States
(12) Patent Application Publication
(10) Pub. No.: US 2016/0133741 A1
(43) Pub. Date: May 12, 2016

(54) SILICON CARBIDE SEMICONDUCTOR DEVICE AND METHOD FOR MANUFACTURING THE SILICON CARBIDE SEMICONDUCTOR DEVICE

(71) Applicant: TOYOTA JIDOSHA KABUSHIKI KAISHA, Toyota-shi (JP)

(72) Inventors: Hideo MATSUKI, Obu-shi (JP); Jun SAKAKIBARA, Nagoya-shi (JP); Sachiko AOI, Nagakute-shi (JP); Yukihiko WATANABE, Nagakute-shi (JP); Atsushi ONOGI, Toyota-shi (JP)

(73) Assignee: TOYOTA JIDOSHA KABUSHIKI KAISHA, Toyota-shi (JP)

(21) Appl. No.: 14/929,742

(22) Filed: Nov. 2, 2015

(30) Foreign Application Priority Data
Nov. 6, 2014 (JP) 2014-226051

(51) Int. Cl. H01L 29/78; H01L 29/66; H01L 29/08; H01L 29/06; H01L 29/16; H01L 29/10

(52) U.S. Cl. CPC H01L 29/7813; H01L 29/7811; H01L 29/1608; H01L 29/1095; H01L 29/086; H01L 29/0696; H01L 29/063; H01L 29/0619; H01L 29/66734

(57) ABSTRACT

A silicon carbide semiconductor device includes a MOSFET and a peripheral high-breakdown-voltage structure. A source region has a first recess. Trenches extend from the bottom of the first recess. A gate insulating film has an extension the shape of which follows the shape of the first recess. The surface of a gate electrode is positioned to be flush with or below the upper surface of the extension.

### INCORPORATION BY REFERENCE

The disclosure of Japanese Patent Application No. 2014-226051 filed on Nov. 6, 2014 including the specification, drawings and abstract is incorporated herein by reference in its entirety.

### BACKGROUND OF THE INVENTION

1. Field of the Invention

The invention relates to a silicon carbide (hereinafter referred to as SiC) semiconductor device having a trench gate and a method for manufacturing the silicon carbide semiconductor device.

2. Description of Related Art

JP-A-2011-101036 discloses a SiC semiconductor device provided with a MOSFET having a trench gate in a cell region and a peripheral high-breakdown-voltage structure in a peripheral region surrounding the cell region.

The SiC semiconductor device includes a semiconductor substrate that is composed of an n⁺-type SiC and is provided with an n⁻-type drift layer thereon. In the cell region, a p-type base region is formed in a surface portion of the n⁻-type drift layer, and an n⁺-type source region and a p⁺-type contact layer are formed in the upper portion of the p-type base region. A trench penetrates the p-type base region and the n⁺-type source region to the n⁻-type drift layer. A gate electrode is formed on a gate oxide film that is formed on the surface of the trench to form a trench gate structure for the MOSFET.

The peripheral region surrounding the cell region has a mesa structure that is deeper than the p-type base region formed in the cell region and reach the n⁻-type drift layer. At a boundary portion between the cell region and the peripheral region, a p-type RESURF layer extends from a side wall to a bottom surface at a step of the mesa structure. Furthermore, a plurality of p-type guard ring layers is formed on the bottom of the mesa structure to surround the circumference of the p-type RESURF layer, thereby forming a peripheral high-breakdown-voltage structure.

This structure allows the p-type guard ring layers to have equipotential lines spaced at adequate distances under a high drain voltage so as to reduce the concentration of the electric field, resulting in a semiconductor device having a high breakdown voltage.

In manufacture of SiC semiconductor devices having the above structure, if the trench for forming the trench gate structure and the mesa structure could be simultaneously formed by a single etching step capable of etching a deep position, the manufacturing process would be simplified.

### SUMMARY OF THE INVENTION

In the simultaneous formation of the trench and the mesa structure, the trench should be deeper than the p-type base region; hence, the depth of the mesa structure is also inevitably deep. The excessively deep mesa structure, however, leads to a reduction in thickness of a p-type RESURF layer and a p-type guard ring layer formed on the mesa structure, resulting in insufficient breakdown voltage. Accordingly, it is essential to form a trench with a predetermined depth and a mesa structure with a depth not too deep. The requirement of such precise depth control results in a narrow process margin.

In the SiC semiconductor device, the MOSFET in the cell region is provided with a gate wiring layer and a source electrode formed above the trench gate structure and a drain electrode formed on the back side of the n⁺-type substrate. In this MOSFET, an interlayer insulating film is disposed above the gate electrode to achieve insulation between the gate wiring layer or source electrode and the gate electrode. The interlayer insulating film should have a predetermined thickness sufficient for secure insulation. The excess protrusion of the interlayer insulating film from the substrate, however, causes step differences in the source electrode, resulting in disadvantages, such as a reduction in adhesion between the source electrode and bonding wires, and low patterning accuracy of the gate wiring layer and the source electrode.

Furthermore, in the SiC semiconductor device, no regard is given to the heights of the surfaces of the gate electrode and gate insulating film in the trench gate structure, and thus the unevenness of the substrate surface can increase. Excess unevenness of the substrate surface may cause problems such as generation of residues in patterning in the subsequent steps of producing the semiconductor device, thus precluding a reduction in feature size of the element.

The invention provides a method for manufacturing a SiC semiconductor device capable of simultaneous formation of a trench for forming the trench gate structure and a mesa structure, without a reduction in breakdown voltage of the peripheral high-breakdown-voltage structure. The invention also provides a SiC semiconductor device having a structure capable of minimizing the height of the protruding interlayer insulating film. Furthermore, the invention provides a SiC semiconductor device having a small feature size.

A first aspect of the present invention is a silicon carbide semiconductor device including: a MOSFET including a substrate of a first or second conductivity type including silicon carbide, a drift layer of a first conductivity type including silicon carbide, the drift layer being disposed on the substrate and having an impurity concentration lower than the impurity concentration of the substrate, a base region of a second conductivity type including silicon carbide, the base region being disposed on the drift layer in a cell region, a source region of a first conductivity type including silicon carbide, the source region being disposed on the base region and having an impurity concentration higher than the impurity concentration of the drift layer, a plurality of trenches, each of the trenches extending in a longitudinal direction and being deeper than the source region and the base region to reach the drift layer, the source region and the base region being disposed on both sides of the trenches, a deep layer of a second conductivity type, the deep layer being disposed in surface portions of the drift layer under the base region between two adjacent trenches, the bottoms of the deep layer being disposed below the bottom of each of the trenches, a gate insulating film disposed on the surface of each of the trenches, a gate electrode disposed on the gate insulating film in each of the trenches, an interlayer insulating film covering the gate electrode and the gate insulating film, the interlayer insulating film having a contact hole, a source electrode electrically connected to the source region and the base region through the contact hole, and a drain electrode disposed on the back side of the substrate; and a peripheral high-breakdown-voltage structure including second-conductivity-type impurity layers at the bottom of a recessed mesa structure disposed on a peripheral region surrounding the cell region, the mesa structure being deeper than the source region and the base region to reach the drift layer, wherein the source region has a first recess, each of the trenches extends from the bottom of the first recess, the gate insulating film has an extension following the shape of the first recess, and the top surface of the gate electrode is flush with or below the top surface of the extension.

Thus, the interlayer insulating film is formed on the gate insulating film having the second recess, so that the interlayer insulating film has a second recess lower than the other portions. Consequently, the protrusion of the interlayer insulating film (the height of the step between the interlayer insulating film and its surroundings), which remains at the position of the trench gate structure after the patterning, can be reduced compared to a case without the second recess. Such a process can improve the surface flatness of the electrode material for forming the source electrode and the gate wiring layer disposed on the interlayer insulating film, and thus the patterning accuracy for them.

A second aspect of the present invention is a silicon carbide semiconductor device including: a MOSFET including a substrate of a first or second conductivity type including silicon carbide, a drift layer of a first conductivity type including silicon carbide, the drift layer being disposed on the substrate and having an impurity concentration lower than the impurity concentration of the substrate, a base region of a second conductivity type including silicon carbide, the base region being disposed on the drift layer in a cell region, a source region of a first conductivity type including silicon carbide, the source region being disposed on the base region and having an impurity concentration higher than the impurity concentration of the drift layer, a plurality of trenches, each of the trenches extending in a longitudinal direction and being deeper than the source region and the base region to reach the drift layer, the source region and the base region being disposed on both sides of the trenches, a deep layer of a second conductivity type, the deep layer being disposed in surface portions of the drift layer under the base region between two adjacent trenches, the bottoms of the deep layer being disposed below the bottom of each of the trenches, a gate insulating film disposed on the surface of each of the trenches, a gate electrode disposed on the gate insulating film in each of the trenches, an interlayer insulating film covering the gate electrode and the gate insulating film, the interlayer insulating film having a contact hole, a source electrode electrically connected to the source region and the base region through the contact hole, and a drain electrode disposed on the back side of the substrate; and a peripheral high-breakdown-voltage structure including second-conductivity-type impurity layers surrounding the cell region, the second-conductivity-type impurity layers being at the bottom of a recessed mesa structure disposed on a peripheral region surrounding the cell region, the mesa structure being deeper than the source region and the base region to reach the drift layer, wherein the source region has a first recess, each of the trenches extends from the bottom of the first recess, the gate insulating film has an extension following the shape of the first recess, and the top surface of the gate electrode is flush with or below the top surface of the extension of the gate insulating film.

Thus, the surface of the gate electrode is flush with or below the surface of the gate insulating film. Such a high surface flatness reduces the unevenness in the subsequent steps of producing the semiconductor device, leading to reduced residues which may occur during patterning, facilitating a reduction in feature size of the semiconductor device.

A third aspect of the present invention is a method for manufacturing a silicon carbide semiconductor device including: (a) forming a drift layer of a first conductivity type including silicon carbide on a substrate of a first or second conductivity type including of silicon carbide, the drift layer having an impurity concentration lower than the impurity concentration of the substrate; (b) forming a deep layer of a second conductivity type on a surface portion of the drift layer in a cell region and second-conductivity-type impurity layers surrounding the cell region in a peripheral region surrounding the cell region; (c) forming a base region of a second conductivity type including silicon carbide on the deep layer, the second-conductivity-type impurity layers, and the drift layer; (d) forming a first recess in the base region, forming a first-conductivity-type impurity layer including silicon carbide on the base region and the first recess, and then removing the first-conductivity-type impurity layer other than the portion on the first recess so as to leave a source region on the first recess and a second recess on the surface of the source region, the first-conductivity-type impurity layer having an impurity concentration higher than that of the drift layer; (e) forming a trench extending from the bottom surface of the second recess in the source region through the base region to the drift layer and having a longitudinal direction along an extension direction of the deep layer such that the trench is shallower than the deep layer, and at the same time, forming a recessed mesa structure by removing the base region in the peripheral region to expose the drift layer such that a peripheral high-breakdown-voltage structure with the second-conductivity-type impurity layers is disposed at the bottom of the recessed mesa structure; (f) forming a gate insulating film having an extension following the shape of the second recess in the trench including the surface of the second recess; (g) forming a gate electrode on the gate insulating film in the trench; (h) forming an interlayer insulating film covering the gate electrode and the gate insulating film; (i) forming a contact hole in the interlayer insulating film, and a source electrode electrically connected to the source region and the base region through the contact hole; and (j) forming a drain electrode on the back side of the substrate.

Thus, such a simultaneous formation of a trench and a mesa structure can unify the processes for formation of the trench and the mesa, and thus simplify the manufacturing process. In the formation of the trench, the second recess formed in the source region allows the trench to be formed at a position deeper than the mesa structure.

Accordingly, the height of the protruding trench from the base region toward the drift layer is ensured in the cell region without excessively etching the second-conductivity-type impurity layer formed on the bottom surface of the mesa structure in the peripheral region. In other words, a trench having a predetermined depth can be achieved without formation of an excessively deep mesa structure. Consequently, this process eliminates the need for fine depth control, resulting in a larger process margin.

Reference numerals in parentheses of each of the above described means indicate correspondence to specific means described in embodiments that will be described later.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a cross-sectional view of a SiC semiconductor device according to a first embodiment;

FIG. 2A is a cross-sectional view illustrating one of a step of a manufacturing process of the SiC semiconductor device shown in FIG. 1;

FIG. 2B is a cross-sectional view illustrating one of a step of a manufacturing process of the SiC semiconductor device shown in FIG. 1;

FIG. 2C is a cross-sectional view illustrating one of a step of a manufacturing process of the SiC semiconductor device shown in FIG. 1;

FIG. 2D is a cross-sectional view illustrating one of a step of a manufacturing process of the SiC semiconductor device shown in FIG. 1;

FIG. 3A is a cross-sectional view illustrating one of a step of a manufacturing process of the SiC semiconductor device shown in FIG. 1;

FIG. 3B is a cross-sectional view illustrating one of a step of a manufacturing process of the SiC semiconductor device shown in FIG. 1;

FIG. 3C is a cross-sectional view illustrating one of a step of a manufacturing process of the SiC semiconductor device shown in FIG. 1;

FIG. 3D is a cross-sectional view illustrating one of a step of a manufacturing process of the SiC semiconductor device shown in FIG. 1;

FIG. 4A is a cross-sectional view illustrating one of a step of a manufacturing process of the SiC semiconductor device shown in FIG. 1;

FIG. 4B is a cross-sectional view illustrating one of a step of a manufacturing process of the SiC semiconductor device shown in FIG. 1;

FIG. 4C is a cross-sectional view illustrating one of a step of a manufacturing process of the SiC semiconductor device shown in FIG. 1;

FIG. 4D is a cross-sectional view illustrating one of a step of a manufacturing process of the SiC semiconductor device shown in FIG. 1;

FIG. 5 is a cross-sectional view of a SiC semiconductor device according to a second embodiment; and

FIG. 6A is a cross-sectional view illustrating one of a step of a manufacturing process of the SiC semiconductor device shown in FIG. 5.

FIG. 6B is a cross-sectional view illustrating one of a step of a manufacturing process of the SiC semiconductor device shown in FIG. 5.

FIG. 6C is a cross-sectional view illustrating one of a step of a manufacturing process of the SiC semiconductor device shown in FIG. 5.

FIG. 6D is a cross-sectional view illustrating one of a step of a manufacturing process of the SiC semiconductor device shown in FIG. 5.

### DETAILED DESCRIPTION OF EMBODIMENTS

Hereinafter, embodiments of the invention will be described with reference to the accompanying drawings. In each of the following embodiments, the same reference numeral is given to the same or equivalent parts in the drawings.

### First Embodiment

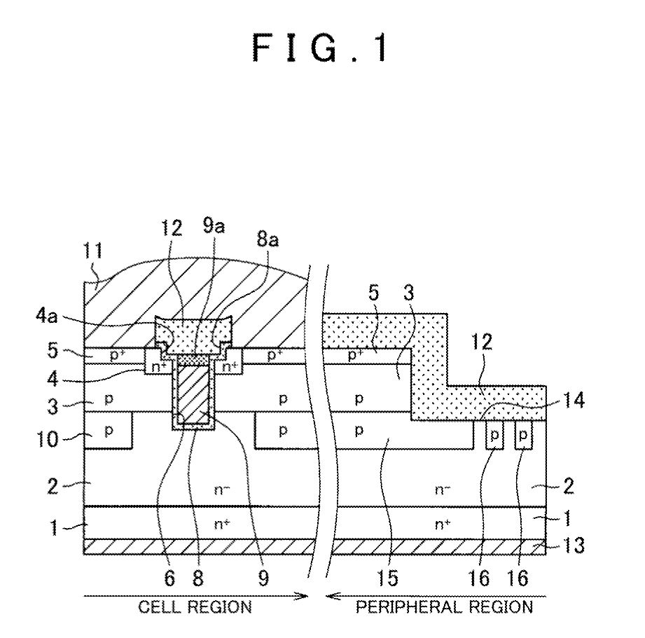

A first embodiment of the invention will be described. A SiC semiconductor device according to the first embodiment includes a cell region having a MOSFET and a peripheral region having a peripheral high-breakdown-voltage structure surrounding the cell region as shown in FIG. 1.

The SiC semiconductor device includes an n⁺-type SiC semiconductor substrate 1 having a principal surface of a Si-plane (i.e., the direction perpendicular to the substrate is the direction of plane [0001]), a concentration of an n-type impurity, such as nitrogen, of, for example, 1.0×10¹⁹/cm³, and a thickness of about 300 μm. An n⁻-type SiC drift layer 2 having a concentration of an n-type impurity, such as nitrogen, of, for example, 3.0×10¹⁵ to 10.0×10¹⁵/cm³ and a thickness of about 5 to 15 μm is formed on the surface of the n⁺-type substrate 1. Although the impurity concentration of the n⁻-type drift layer 2 can be constant in the depth direction, the concentration is preferably gradually varied in such a manner that a portion of the n⁻-type drift layer 2 adjacent to the n⁺-type substrate 1 contains a higher concentration of impurity than a portion of the n⁻-type drift layer 2 away from the n⁺-type substrate 1. For example, it is preferred in the n⁻-type drift layer 2 that the impurity concentration at a distance between about 3 μm and about 5 μm from the surface of the n⁺-type substrate 1 be about 2.0×10¹⁵/cm³ higher than that of the other portions. Such a configuration can reduce the internal resistance of the n⁻-type drift layer 2 and thus reduce the on-resistance of the device.

A p-type base region 3 is formed in a surface portion of the n⁻-type drift layer 2, while an n⁺-type source region 4 and a p⁺-type contact layer 5 for contact use in the p-type base region 3 are formed in an upper portion of the p-type base region 3.

The p-type base region 3 and the p⁺-type contact layer 5 contain p-type impurities, such as boron and aluminum. The n⁺-type source region 4 contains n-type impurities, such as phosphorus. The p-type base region 3 may have a p-type impurity concentration of for example, 5.0×10¹⁵ to 5.0×10¹⁶/cm³ and may have a thickness of about 1.0 to 2.0 μm. The n⁺-type source region 4 may have an n-type impurity concentration in the surface portion (surface concentration) of, for example, 1.0×10²¹/cm³ and may have a thickness of about 0.3 μm. The p⁺-type contact layer 5 may have a p-type impurity concentration in the surface portion of, for example, 1.0×10²¹/cm³ and may have a thickness of about 0.3 μm.

The n⁺-type source region 4 is disposed on either side of the trench gate structure described below. The p⁺-type contact layer 5 is disposed on the opposite side, remote from the trench gate structure, of the n⁺-type source region 4. The n⁺-type source region 4 has a recess 4a at an entrance corner of a trench 6, which will be described below, for forming the trench gate structure.

The trench 6 extends from the bottom surface of the recess 4a through the p-type base region 3 and n⁺-type source region 4 to the n⁻-type drift layer 2. The trench 6 is, for example, 0.3 to 2.0 μm in width, and 1.0 to 2.0 μm or more in depth. The p-type base region 3 and the n⁺-type source region 4 are in contact with the side face of the trench 6.

Furthermore, the inner wall of the trench 6 is covered with a gate oxide film 8 functioning as a gate insulating film, and a gate electrode 9 made of doped Poly-Si is formed on the gate oxide film 8. The gate oxide film 8 is formed, for example, by thermal oxidization of the inner wall surface of the trench 6. The gate oxide film 8 formed on the inner wall and the bottom of the trench 6 has a thickness of, for example, about 100 nm. The gate oxide film 8 is formed on the inner wall surfaces of the trench 6 in the n⁺-type source region 4 and in the recessed portion at the entrance of the trench 6, extending to the exterior of the trench 6 and the recess 4a. Accordingly, the gate oxide film 8 has an extension 8a the shape of which follows the shape of the recess 4a.

The surface portion of the gate electrode 9 is partially oxidized to cover the surface of the gate electrode 9 with a cap oxide film 9a. The surface of the cap oxide film 9a is flush with the bottom surface of the extension 8a of the gate oxide film 8 which is formed by the recess 4a in the n⁺-type source region 4.

The trench gate structure is prepared in such a manner. The trench gate structure extends in a line in the longitudinal direction perpendicular to the drawing in FIG. 1. Multiple trench gate structures are disposed parallel to one another in the horizontal direction in the drawing of FIG. 1. Furthermore, each of the n⁺-type source region 4 and the p⁺-type contact layer 5 extends in the longitudinal direction of the trench gate structure.

Multiple p-type deep layers 10 are provided below the p-type base region 3 in the n⁻-type drift layer 2 so as to be separated by a predetermined distance from the side of the trench 6 in the trench gate structure. The p-type deep layers 10 each extend more deeply than the bottom of the trench 6, and have a depth of, for example, 0.6 to 1.0 μm from the bottom of the p-type base region 3. Each p-type deep layer 10 is doped with a p-type impurity such as boron or aluminum at a concentration of 1.0×10¹⁷/cm³ to 1.0×10¹⁹/cm³, for example, 5.0×10¹⁷/cm³. These p-type deep layers 10 are disposed in stripes parallel to one another in the longitudinal direction of the trench gate structure.

A source electrode 11 and a gate wiring layer (not shown) are formed on the surfaces of the n⁺-type source region 4, the p⁺-type contact layer 5, and the gate electrode 9. The source electrode 11 and the gate wiring layer are made of a plurality of metals (for example, Ni and Al). In this case, at least the portions thereof in contact with n-type SiC (specifically, the n⁺-type source region 4 and the gate electrode 9 of an n-doped structure) are made of a metal that can make an ohmic contact with the n type SiC, and at least the other portions in contact with the p-type SiC (specifically, the p⁺-type contact layer 5 and the gate electrode 9 of a p-doped structure) are made of a metal that can make an ohmic contact with the p-type SiC.

The source electrode 11 and the gate wiring layer are patterned on an interlayer insulating film 12 to be electrically isolated from each other. Via contact holes in the interlayer insulating film 12, the source electrode 11 is electrically connected to the n⁺-type source region 4 and the p⁺-type contact layer 5 and the gate wiring layer is electrically connected to the gate electrode 9.

The interlayer insulating film 12 is formed of, for example, an oxide film, having a thickness of, for example, 0.7 μm. As described above, the gate oxide film 8 has the extension 8a, and the cap oxide film 9a is flush with the bottom surface of the extension 8a, so that these films have recessed surfaces. The interlayer insulating film 12 extends into the depressions of the surface of the gate oxide film 8 and the cap oxide film 9a, which structure thus leads to a reduction in height of the interlayer insulating film 12, i.e., the height from the uppermost surface of the n⁺-type source region 4. Accordingly, the step of contact holes for exposing the n⁺-type source region 4 and the p⁺-type contact layer 5 can be reduced, and the unevenness of the surface of the source electrode 11 formed thereon can be reduced.

The back side of the n⁺-type substrate 1 is provided with a drain electrode 13 which is in electrically connected to the n⁺-type substrate 1. Thus, the MOSFET having the n-channel inverted-type trench gate structure is formed.

The peripheral region surrounding the cell region is formed as follows.

In the peripheral region, a mesa structure 14 is formed of a recess having a depth that is deeper than the p-type base region 3 formed in the cell region, which reaches the n⁻-type drift layer 2, and is shallower than the bottom surface of the trench 6 (the deepest point). At a boundary portion between the cell region and the peripheral region, a p-type RESURF layer 15 extends from the lower part of the p-type base region 3 to the bottom surface of the mesa structure 14 across the step portion of the mesa structure 14 so as to surround the periphery of the cell region. Also, a plurality of p-type guard ring layers 16 surrounds the circumference of the p-type RESURF layer 15. The p-type layers including the p-type RESURF layer 15 and the p-type guard ring layers 16 form a peripheral high-breakdown-voltage structure.

It should be noted that the n⁺-type layer and a same-potential ring electrode electrically connected to the n⁺-type layer may be formed to surround the circumferences of the p-type RESURF layer 15 and the p-type guard ring layers 16 and to form a peripheral high-breakdown-voltage structure, although not shown in the drawings.

The p-type RESURF layer 15 extends, for example, by about 20 μm, from the boundary portion between the cell region and the peripheral region toward the exterior of the cell region. The p-type guard ring layers 16 (for example, six layers) having a width, in the radial direction, of 2 μm and a radial spacing of 1 μm are sequentially formed, wherein the layer at the innermost peripheral side is, for example, 0.5 μm away from the p-type RESURF layer 15.

The p-type RESURF layer 15 and the p-type guard ring layers 16 have the same depth to the bottom (i.e., the deepest position) and the same p-type impurity concentration as those of the p-type deep layers 10. Thus, such a configuration provides the SiC semiconductor device according to the embodiment.

The MOSFET of such an inverted-type trench gate structure provided to the SiC semiconductor device operates as follows.

Before a gate voltage equal to or higher than the threshold value is applied to the gate electrode 9, no channel region is formed on the side face of the trench 6 in the p-type base region 3. Even if a positive voltage is applied to the drain electrode 13, the PNP junction structure formed by the n⁻-type drift layer 2, the p-type base region 3 and the n⁺-type source region 4 blocks electron transfer and thus inhibits current flow between the source electrode 11 and the drain electrode 13.

When the MOSFET is in an ON state (for example, gate voltage: 20 V, drain voltage: 1 V, and source voltage: 0 V), the gate electrode 9 is supplied with a gate voltage of 20 V which is equal to or higher than the threshold value, and the p-type base region 3 is thereby inverted to form a channel region on the side face of the trench 6. Thus, electrons injected from the source electrode 11 flow through the n⁺-type source region 4 and the channel region in p-type base region 3 and then reach the n⁻-type drift layer 2. Thus, current flows between the source electrode 11 and the drain electrode 13.

When the MOSFET is in an OFF state, for example, gate voltage: 0 V, drain voltage: 650 V, and source voltage: 0 V), the drain electrode 13 is reverse-biased by a voltage applied to the drain electrode 13. Consequently, depletion layers extends from the interfaces, for example, between each of the p-type deep layers 10 and n⁻-type drift layer 2 and between the p-type RESURF layer 15 and the n⁻-type drift layer 2. In the embodiment, since the p-type deep layers 10 and the p-type RESURF layer 15 have an impurity concentration much higher than that of the n⁻-type drift layer 2, the depletion layers extend mostly to the n⁻-type drift layer 2.

Furthermore, since the p-type deep layers 10 and the p-type RESURF layer 15 have the same depth, depletion layers extending from the interfaces between each of the p-type deep layers 10 and n⁻-type drift layer 2 and between the p-type RESURF layer 15 and the n⁻-type drift layer 2 readily merge to extend to the p-type guard ring layers 16. Similarly, the equipotential lines in the depletion layers are substantially horizontal to the substrate plane below the p-type deep layers 10 and the p-type RESURF layer 15 and terminate proximal to p-type guard ring layers 16. This configuration allows breakdown to occur at p-type guard ring layers 16 rather than the p-type deep layers 10 to achieve a semiconductor device with a high breakdown voltage.

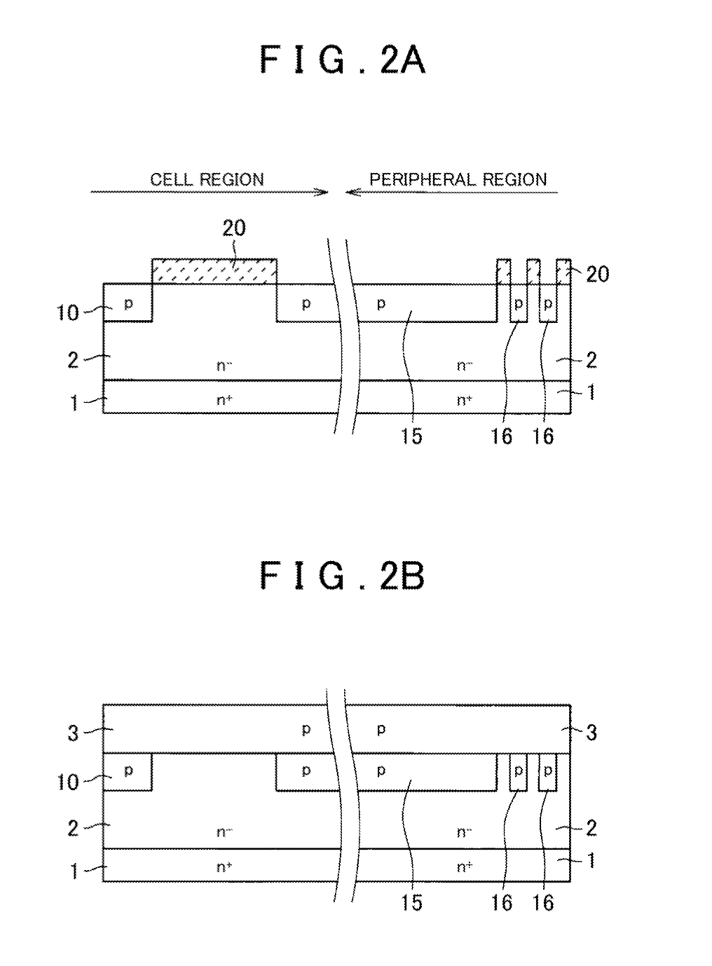

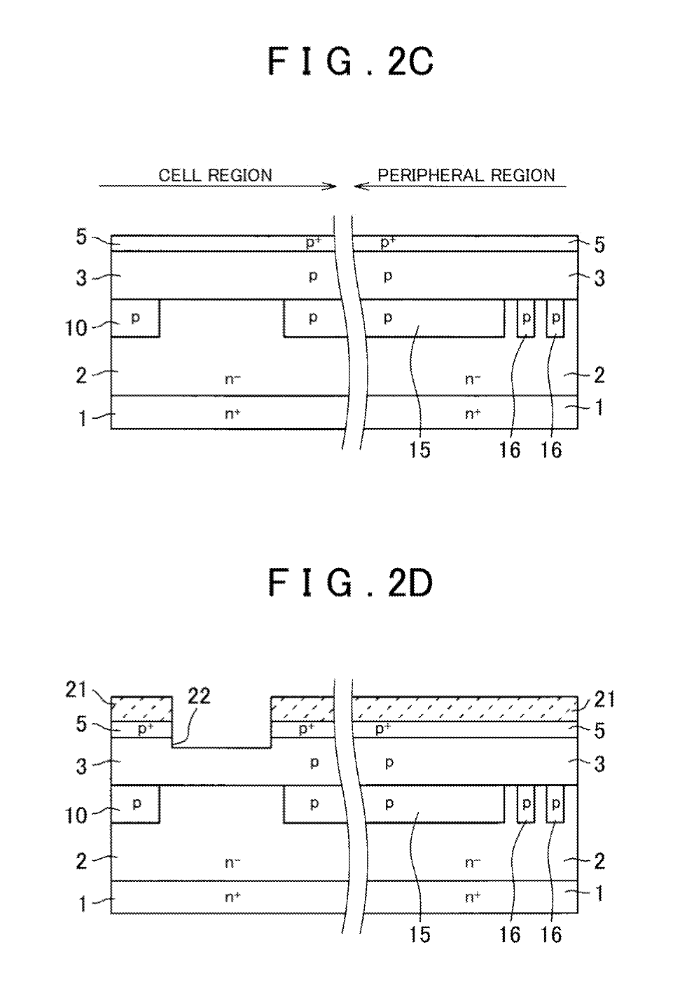

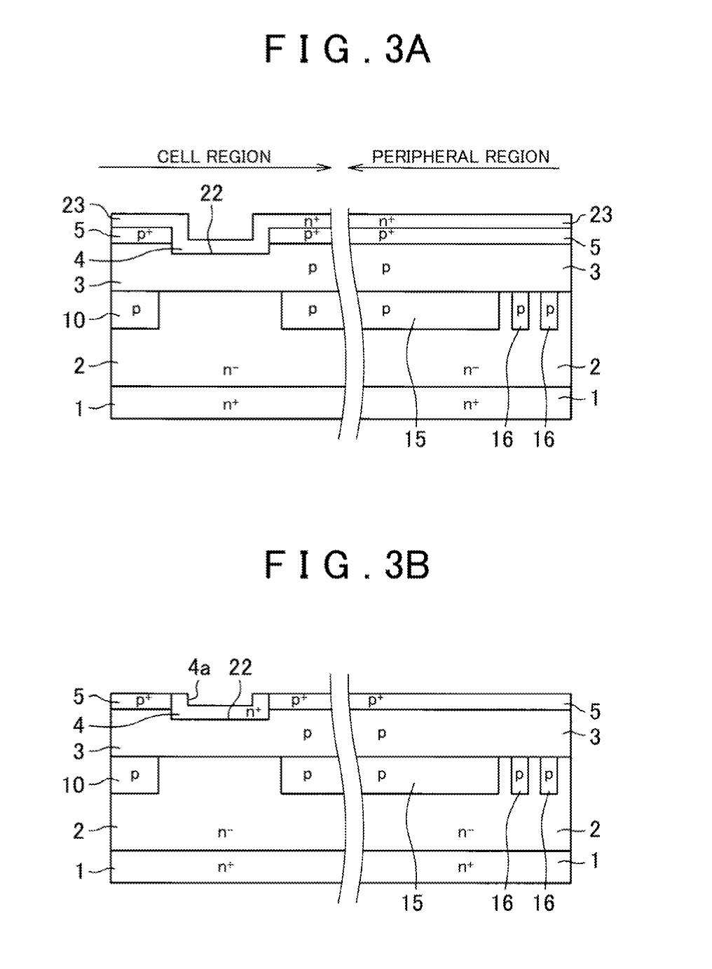

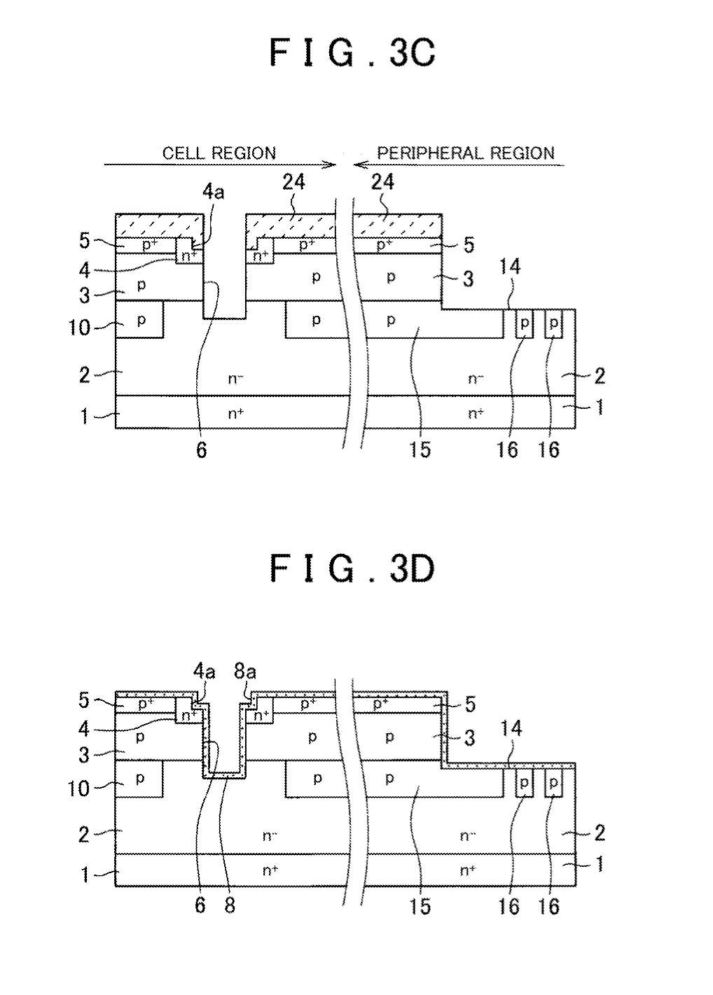

A method for manufacturing a SiC semiconductor device having a MOSFET of an inverted-type trench gate structure according to the embodiment will now be described.

[Step in FIG. 2A]: An n⁻-type SiC drift layer 2 is epitaxially grown on the surface of an n⁺-type SiC substrate 1 prepared in advance. Subsequently, a mask 20 made of, for example, LTO, is formed on the surface of the n⁻-type drift layer 2. The mask 20 is then etched through photolithography in areas where the p-type deep layers 10, a p-type RESURF layer 15, and p-type guard ring layers 16 are to be formed. An impurity (for example, boron or aluminum) of a p conductivity type is implanted through the mask 20 to complete the p-type deep layers 10 and p-type guard ring layers 16. Thereafter, the mask 20 is removed.

[Step in FIG. 2B]: A p-type impurity layer is epitaxially grown on the surface of the n⁻-type drift layer 2 to form a p-type base region 3.

[Step in FIG. 2C]: A p-type impurity layer having a higher concentration of p-type impurity than the p-type base region 3 is epitaxially grown on the p-type base region 3 to form a p⁺-type contact layer 5.

[Step in FIG. 2D]: A mask 21 is formed on the p-type base region 3, and is then etched through photolithography in an area where an n⁺-type source region 4 is to be formed, the area being wider than where a trench gate structure is to be formed. The etching through the mask 21 is continued to a predetermined depth to remove the p⁺-type contact layer 5 and a portion of the p-type base region 3, thereby forming a recess 22. The bottom of the recess 22 is higher than the bottom of the p-type base region 3, and is at the same concentration as the bottom of an n⁺-type source region 4 formed in a later step. Furthermore, the width of the recess 22 should be greater than that of a trench 6 and, the width in the embodiment is set to have a distance between the distal edges of n⁺-type source region 4 to the trench 6. The mask 21 is then removed.

[Step in FIG. 3A]: An n-type impurity layer 23 having a high impurity concentration and a predetermined thickness is epitaxially grown on the p⁺-type contact layer 5 and on the recess 22.

[Step in FIG. 3B]: In a cell region and a peripheral region, the n-type impurity layer 23 formed on the surface of the p⁺-type contact layer 5 is removed by Chemical Mechanical Polishing (CMP) while the portion on the recess 22 is left. The n-type impurity layer 23 formed in the recess 22 functions as the n⁺-type source region 4 and a recess 4a is formed on the surface of the n⁺-type source region 4,

[Step in FIG. 3C]: An etching mask 24 is deposited on the n⁺-type source region 4 and the p⁺-type contact layer 5 and is etched in areas where a recess for forming the trench 6 and a mesa structure 14 are to be formed. Subsequent anisotropic etching through an etching mask 24 is carried out to form the trench 6 and the recessed mesa structure 14 at the same time. The etching mask 24 is then removed.

Such a simultaneous formation of the trench 6 and the mesa structure 14 can unify the processes for formation of the trench and the mesa, and thus simplify the manufacturing process. In the formation of the trench 6, the recess 4a formed in the n⁺-type source region 4 allows the trench 6 to be formed at a position deeper than the mesa structure 14.

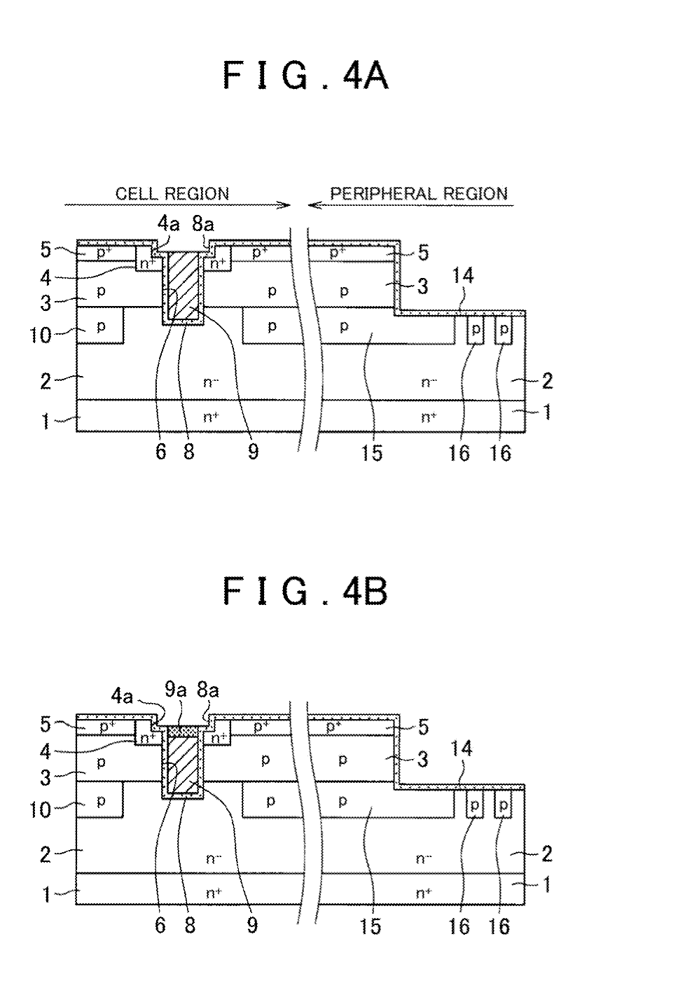

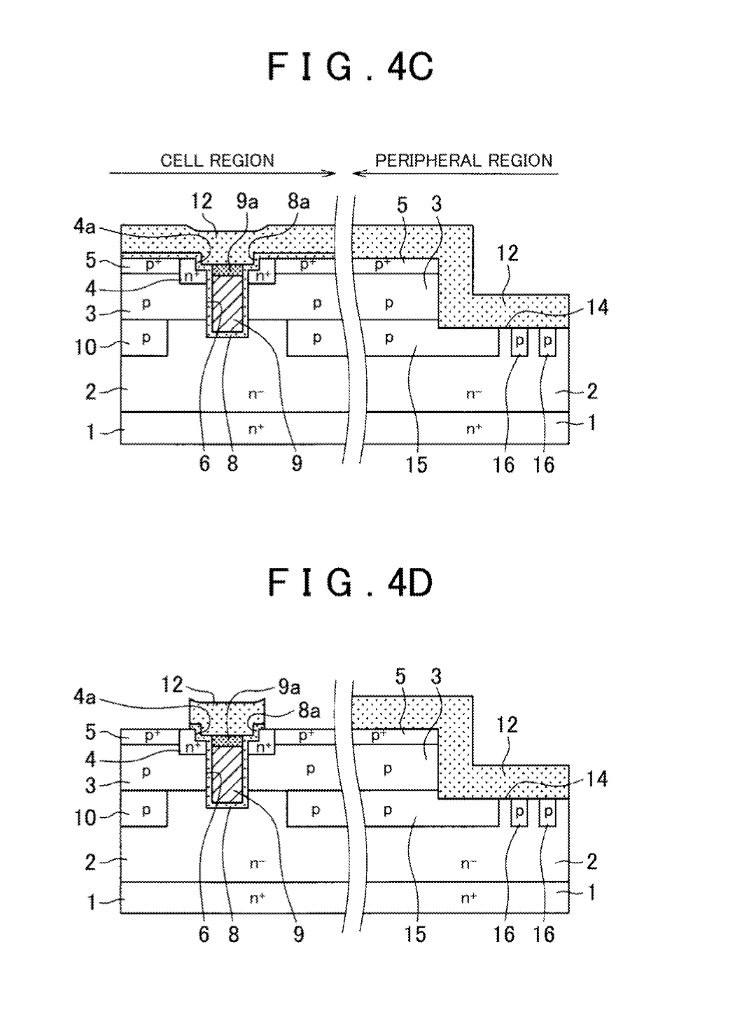

Accordingly, the depth of the trench 6 protruding from the p-type base region 3 into the n⁻-type drift layer 2 is ensured in the cell region without excess etching of the p-type RESURF layer 15 and the p-type guard ring layers 16 formed on the bottom surface of the mesa structure 14 in the peripheral region. In other words, the trench 6 having a predetermined depth can be formed without formation of an excessively deep mesa structure 14. Consequently, this process eliminates the need for fine depth control, providing a larger process margin.

[Step in FIG. 3D]: After an optional step for modifying the inner surface of the trench such as sacrificial oxidation, a gate oxide film 8 having a predetermined thickness is formed by, for example, thermal oxidation over the entire surface of the substrate including the surface of the trench 6. Thus, on the n⁺-type source region 4, the gate oxide film 8 has an extension 8a the shape of which follows the shape of the recess 4a.

[Step in FIG. 4A]: A poly-Si layer doped with an n-type impurity was deposited on the surface of the gate oxide film 8. The gate oxide film 8 and the gate electrode 9 are then left in the trench 6 through, for example, an etch-back step such that the surface of the gate electrode 9 is flush with the bottom surface of the extension 8a of the gate oxide film 8 Thus, the extension 8a of the gate oxide film 8 remains even after the formation of the gate electrode 9.

[Step in FIG. 4B]: The surface of the gate electrode 9 is thermally oxidized, so that the surface of the gate electrode 9 is covered with a cap oxide film 9a. The surface of the gate electrode 9 is formed so as to be flush with the bottom surface of the extension 8a, and the thickness of the cap oxide film 9a and the increased thickness of the oxide film of the gate oxide film 8 by this thermal oxidation are substantially the same. Consequently, the surface of the cap oxide film 9a is substantially flush with the bottom surface of the extension 8a. The trench gate structure is thereby formed.

[Step in FIG. 4C]: An interlayer insulating film 12 is deposited on the gate oxide film 8 and the gate electrode 9. For example, the interlayer insulating film 12 is deposited into a thickness of about 0.7 μm by Chemical Vapor Deposition (CVD). The interlayer insulating film 12 is partially recessed at a position above the trench gate structure because the extension 8a remains on the gate oxide film 8.

[Step in FIG. 4D]: The interlayer insulating film 12 is patterned through an etching mask (not shown) to form contact holes which partially expose the n⁺-type source region 4 and the p⁺-type contact layer 5 to the interlayer insulating film 12, and to form other contact holes which partially expose the lead portion of the gate electrode 9 in another cross section.

Although the subsequent processes, which are the same as the conventional processes, are not shown in the drawings, an electrode material is deposited so as to fill the contact holes and is patterned to form a source electrode 11 and a gate wiring layer. A drain electrode 13 is formed on the back side of the n⁺-type substrate 1. The SiC semiconductor device shown in FIG. 1 is thereby completed

In the SiC semiconductor device formed as described above, the interlayer insulating film 12 is formed on the gate oxide film 8 having the extension 8a, so that the interlayer insulating film 12 has a sink, which is lower than the other portions, above the extension 8a. Consequently, the protrusion of the interlayer insulating film 12 (the height of the step between the interlayer insulating film 12 and its surroundings), which remains at the position of the trench gate structure after the patterning, can be reduced compared to a case without the extension 8a. The interlayer insulating film 12 can be rounded by a reflow process after the patterning of the interlayer insulating film 12. Even in such a case, the resulting protrusion can be further reduced because of the small original protrusion of the interlayer insulating film 12 that protrudes to the outside of the extension 8a.

Such a process can improve the surface flatness of the electrode material for forming the source electrode 11 and the gate wiring layer disposed on the interlayer insulating film 12, and thus the patterning accuracy for them.

### Second Embodiment

A second embodiment of the invention will now be described. In the second embodiment, the structure of the gate electrode 9 is modified from that in the first embodiment, and the other parts are similar to those in the first embodiment. Only the differences from the first embodiment will be described.

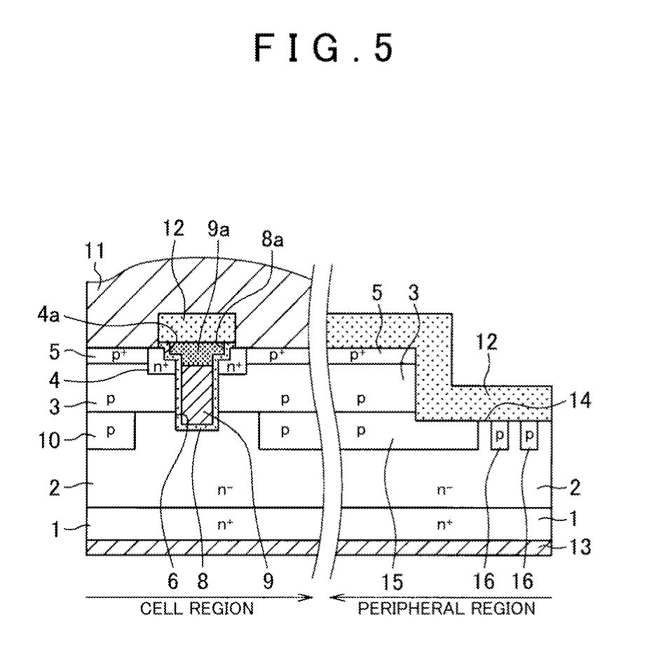

With reference to FIG. 5, in the embodiment, the surface of the cap layer 9a of the gate electrode 9 is flush with the surface of the gate oxide film 8 (the upper surface of the extension 8a). A SiC semiconductor device having such a structure is manufactured as follows:

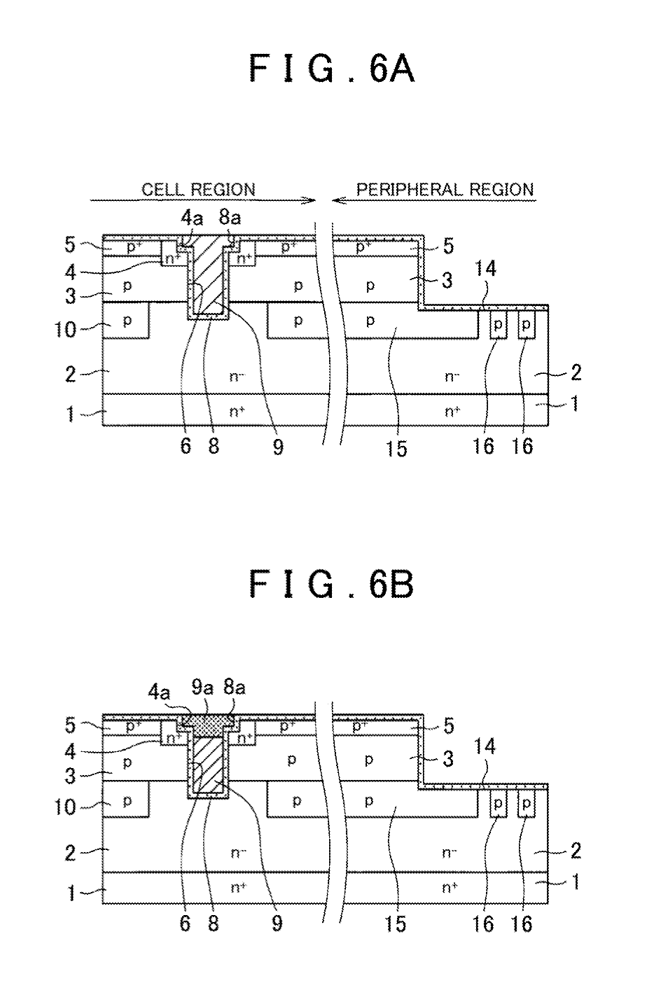

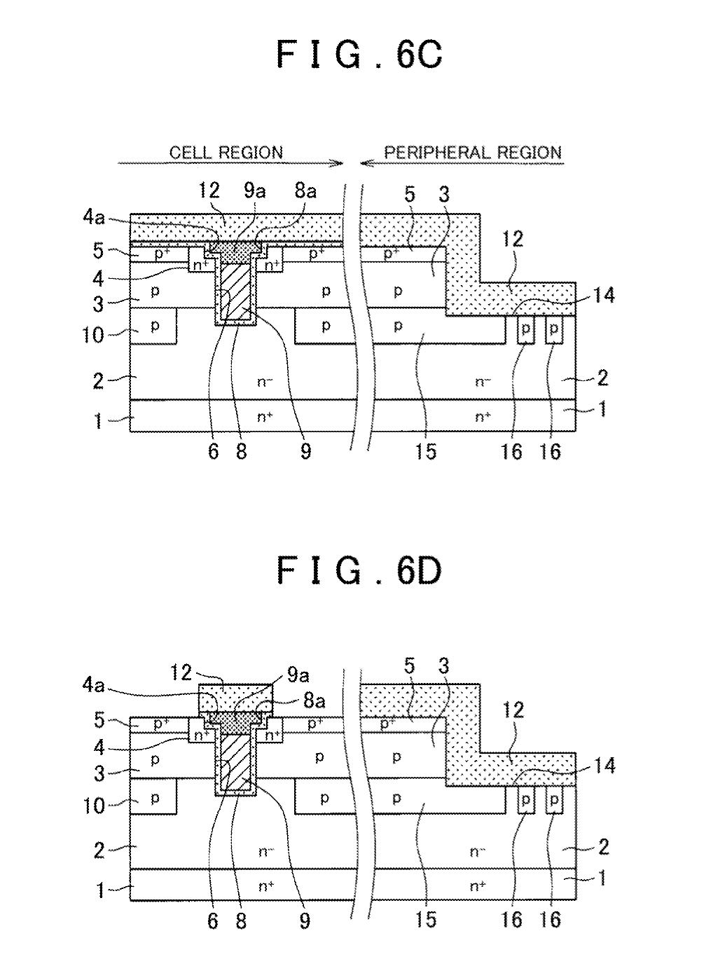

After the processes as shown in FIGS. 2A to 2D and FIGS. 3A to 3D described in the first embodiment, the processes as shown in FIGS. 6A to 6D are performed.

Specifically, in the step shown in FIG. 6A, a process similar to the step shown in FIG. 4A is performed such that the surface of the gate electrode 9 is etched back so as to be flush with the surface of the gate oxide film 8. For example, in the case where the etching apparatus controls an etching endpoint by signal irradiation to an etched surface, the endpoint is controlled based on a reflected signal from the etched surface. In the case where the surface of the gate electrode 9 is formed so as to be flush with the surface of the gate oxide film 8, exposition of the gate oxide film 8 leads to a significant reduction in surface area of the Poly-Si layer, which is a constituent material of the gate electrode 9, and thus a variation of intensity of the signal reflected from the etched surface. Accordingly, the end of the etch-back based on the change in the reflected signal from the surface enables the surface of the gate electrode 9 to be flush with the surface of the gate oxide film 8.

In the following steps shown in FIGS. 6B to 6D, steps of forming, for example, the cap oxide film 9a, the interlayer insulating film 12, and the contact holes are performed, similarly to the steps shown in FIGS. 4B to 4D described in the first embodiment. The SiC semiconductor device of the embodiment shown in FIG. 5 is thereby completed.

Thus, the etch-back of the Poly-Si layer for forming the gate electrode 9 allows the surface of the gate electrode 9 to be flush with the surface of the gate oxide film 8. Accordingly, the surface of the cap oxide film 9a formed in the subsequent step shown in FIG. 6B is also substantially flush with the surface of the gate oxide film 8. Such a high surface flatness reduces the formation of the unevenness in the subsequent steps of producing the semiconductor device, leading to reduced residues which may occur during patterning, allowing a reduction in feature size of the semiconductor device.

### Other Embodiments

The above described embodiments should not be construed to limit the invention, and can be modified within the scope of the appended claims.

For example, in the step shown in FIG. 3A, an n-type impurity layer 23 having a high impurity concentration and a predetermined thickness is epitaxially grown on the p⁺-type contact layer 5 and on the recess 22, and the n-type impurity layer 23 is left only inside the recess 22 to form an n⁺-type source region 4. This embodiment is a mere example of the step for forming the n⁺-type source region 4, and any other appropriate step can be employed for forming the n⁺-type source region 4.

For example, after the recess 22 is formed in the step shown in FIG. 2D, an n-type impurity is implanted through a mask having an opening in the area where the n⁺-type source region 4 is to be formed. Alternatively, the etching mask for forming the recess 22 used in FIG. 2D can be used for oblique ion-implantation of an n-type impurity to form the n⁺-type source region 4. This process enables the n⁺-type source region 4 to be formed by self-alignment with the recess 22. The recess 4a of the n⁺-type source region 4 is formed by ion-implantation is the same as the recess 22 formed in the step shown in FIG. 2D.

The p⁺-type contact layer 5 is formed by epitaxial growth in the step shown in FIG. 2C. This layer can also be formed by ion-implantation of a p-type impurity into the surface of the p-type base region 3. In this case, the p⁺-type contact layer 5 can be formed after the n⁺-type source region 4, not before the n⁺-type source region 4.

In the above embodiments, the partial surface of the gate electrode 9 is oxidized such that the part of the gate electrode 9 functions as the cap oxide film 9a. Alternatively, the surface of the gate electrode 9 may be in direct contact with the interlayer insulating film 12 without the cap oxide film 9a.

In the above embodiments, the gate oxide film 8 that functions as a gate insulating film is formed by thermal oxidation. Alternatively, the insulating film may be formed by any other process such as CVD.

In the above embodiments, the impurity layers of a second conductivity type, i.e., the p-type RESURF layer 15 and the p-type guard ring layers 16 are formed. Instead at least one of them may be formed in the invention.

In the above embodiments, the MOSFET of the n-channel type in which the first conductivity type is an n-type, and the second conductivity type is a p-type has been described as an example. Alternatively, the invention can be applied to a MOSFET of a p-channel type in which the conductivity types of the respective components are reversed. In the above description, the MOSFET of the trench gate structure has been described as an example. The invention can also be applied to an insulated gate bipolar transistor (IGBT) having the same trench gate structure. In the IGBT, only the conductivity type of the n⁺-type substrate 1 is varied from the n-type to the p-type in the above embodiments, and other structures and the manufacturing process are similar to those in the above embodiments.

What is claimed is:

1. A silicon carbide semiconductor device comprising:
a MOSFET including
a substrate of a first or second conductivity type comprising silicon carbide,
a drift layer of a first conductivity type comprising silicon carbide, the drift layer being disposed on the substrate and having an impurity concentration lower than the impurity concentration of the substrate,
a base region of a second conductivity type comprising silicon carbide, the base region being disposed on the drift layer in a cell region,
a source region of a first conductivity type comprising silicon carbide, the source region being disposed on the base region and having an impurity concentration higher than the impurity concentration of the drift layer,
a plurality of trenches, each of the trenches extending in a longitudinal direction and being deeper than the source region and the base region to reach the drift layer, the source region and the base region being disposed on both sides of the trenches,
a deep layer of a second conductivity type, the deep layer being disposed in surface portions of the drift layer under the base region between two adjacent trenches, the bottoms of the deep layer being disposed below the bottom of each of the trenches,
a gate insulating film disposed on the surface of each of the trenches,
a gate electrode disposed on the gate insulating film in each of the trenches,
an interlayer insulating film covering the gate electrode and the gate insulating film, the interlayer insulating film having a contact hole,
a source electrode electrically connected to the source region and the base region through the contact hole, and
a drain electrode disposed on the back side of the substrate; and
a peripheral high-breakdown-voltage structure including second-conductivity-type impurity layers at the bottom of a recessed mesa structure disposed on a peripheral region surrounding the cell region, the mesa structure being deeper than the source region and the base region to reach the drift layer, wherein
the source region has a first recess,
each of the trenches extends from the bottom of the first recess, the gate insulating film has an extension following the shape of the first recess, and
the top surface of the gate electrode is flush with or below the top surface of the extension.

2. The silicon carbide semiconductor device according to claim 1 wherein a cap oxide film is formed by oxidation of the gate electrode and the top surface of the cap oxide film of the gate electrode is flush with or below the top surface of the extension.

3. The silicon carbide semiconductor device according to claim 1 wherein the MOSFET is an inverted-type MOSFET, wherein an inverted channel region is formed in the boundary area of the base region to the trench by controlling an applied voltage to a gate electrode, such that current flows between the source electrode and the drain electrode through the source region and the drift region.

4. A silicon carbide semiconductor device comprising:
a MOSFET including
a substrate of a first or second conductivity type comprising silicon carbide,
a drift layer of a first conductivity type comprising silicon carbide, the drift layer being disposed on the substrate and having an impurity concentration lower than the impurity concentration of the substrate,
a base region of a second conductivity type comprising silicon carbide, the base region being disposed on the drift layer in a cell region,
a source region of a first conductivity type comprising silicon carbide, the source region being disposed on the base region and having an impurity concentration higher than the impurity concentration of the drift layer,
a plurality of trenches, each of the trenches extending in a longitudinal direction and being deeper than the source region and the base region to reach the drift layer, the source region and the base region being disposed on both sides of the trenches,
a deep layer of a second conductivity type, the deep layer being disposed in surface portions of the drift layer under the base region between two adjacent trenches, the bottoms of the deep layer being disposed below the bottom of each of the trenches,
a gate insulating film disposed on the surface of each of the trenches,
a gate electrode disposed on the gate insulating film in each of the trenches,
an interlayer insulating film covering the gate electrode and the gate insulating film, the interlayer insulating film having a contact hole,
a source electrode electrically connected to the source region and the base region through the contact hole, and
a drain electrode disposed on the back side of the substrate; and
a peripheral high-breakdown-voltage structure including second-conductivity-type impurity layers surrounding the cell region, the second-conductivity-type impurity layers being at the bottom of a recessed mesa structure disposed on a peripheral region surrounding the cell region, the mesa structure being deeper than the source region and the base region to reach the drift layer, wherein
the source region has a first recess,
each of the trenches extends from the bottom of the first recess, the gate insulating film has an extension following the shape of the first recess, and
the top surface of the gate electrode is flush with or below the top surface of the extension of the gate insulating film.

5. The silicon carbide semiconductor device according to claim 4 wherein a cap oxide film is formed by oxidation of the top surface of the gate electrode, and the top surface of the cap oxide film of the gate electrode is flush with or below the top surface of the extension of the gate insulating film.

6. The silicon carbide semiconductor device according to claim 4 wherein the MOSFET is an inverted-type MOSFET, wherein an inverted channel region is formed in the boundary area of the base region to the trench by controlling an applied voltage to a gate electrode, such that current flows between the source electrode and the drain electrode through the source region and the drift region.

7. A method for manufacturing a silicon carbide semiconductor device comprising:
(a) forming a drift layer of a first conductivity type comprising silicon carbide on a substrate of a first or second conductivity type comprising of silicon carbide, the drift layer having an impurity concentration lower than the impurity concentration of the substrate;
(b) forming a deep layer of a second conductivity type on a surface portion of the drift layer in a cell region and second-conductivity-type impurity layers surrounding the cell region in a peripheral region surrounding the cell region;
(c) forming a base region of a second conductivity type comprising silicon carbide on the deep layer, the second-conductivity-type impurity layers, and the drift layer;
(d) forming a first recess in the base region, forming a first-conductivity-type impurity layer comprising silicon carbide on the base region and the first recess, and then removing the first-conductivity-type impurity layer other than the portion on the first recess so as to leave a source region on the first recess and a second recess on the surface of the source region, the first-conductivity-type impurity layer having an impurity concentration higher than that of the drift layer;
(e) forming a trench extending from the bottom surface of the second recess in the source region through the base region to the drift layer and having a longitudinal direction along an extension direction of the deep layer such that the trench is shallower than the deep layer, and at the same time, forming a recessed mesa structure by removing the base region in the peripheral region to expose the drift layer such that a peripheral high-breakdown-voltage structure with the second-conductivity-type impurity layers is disposed at the bottom of the recessed mesa structure;
(f) forming a gate insulating film having an extension following the shape of the second recess in the trench including the surface of the second recess;
(g) forming a gate electrode on the gate insulating film in the trench;
(h) forming an interlayer insulating film covering the gate electrode and the gate insulating film;
(i) forming a contact hole in the interlayer insulating film, and a source electrode electrically connected to the source region and the base region through the contact hole; and
(j) forming a drain electrode on the back side of the substrate.

8. A method for manufacturing a silicon carbide semiconductor device according to claim 7 wherein in step (g), the gate electrode is formed such that the bottom surface of the extension is flush with the top surface of the gate electrode.

9. The method for manufacturing a silicon carbide semiconductor device according to claim 8 wherein step (g) includes oxidizing the top surface of the gate electrode to form a cap oxide film such that the top surface of the cap oxide film of the gate electrode is flush with or below the bottom surface of the extension.

10. The method for manufacturing a silicon carbide semiconductor device according to claim 7 wherein in step (g), the gate electrode is formed such that the top surface of the gate electrode is flush with or below the top surface of the extension of the gate insulating film.

11. The method for manufacturing a silicon carbide semiconductor device according to claim 10 wherein step (g) includes oxidizing the top surface of the gate electrode to form a cap oxide film such that the top surface of the cap oxide film of the gate electrode is flush with or below the top surface of the extension of the gate insulating film.
